(19) United States
(12) Patent Application Publication
(10) Pub. No.: US 2018/0335692 A1
(43) Pub. Date: Nov. 22, 2018

(54) PHASE-SHIFT BLANKMASK AND PHASE-SHIFT PHOTOMASK

(71) Applicant: S&S TECH Co., Ltd., Daegu-si (KR)

(72) Inventors: Kee-Soo NAM, Daegu-si (KR); Cheol SHIN, Daegu-si (KR); Jong-Hwa LEE, Daegu-si (KR); Chul-Kyu YANG, Daegu-si (KR); Chang-Jun KIM, Daegu-si (KR); Seung-Hyup SHIN, Daegu-si (KR); Gil-Woo KONG, Daegu-si (KR)

(73) Assignee: S&S TECH Co., Ltd., Daegu-si (KR)

(21) Appl. No.: 15/975,297

(22) Filed: May 9, 2018

(30) Foreign Application Priority Data
May 18, 2017 (KR) 10-2017-0061699
Apr. 26, 2018 (KR) 10-2018-0048241

(51) Int. Cl. G03F 1/32; G03F 1/46; G03F 1/00; G03F 1/80; G03F 1/60

(52) U.S. Cl. CPC G03F 1/32; G03F 1/46; G03F 1/60; G03F 1/80; G03F 1/0076

(57) ABSTRACT

Disclosed are a phase-shift blankmask and a phase-shift photomask, which includes a phase-shift film made of silicon (Si) or a silicon (Si) compound on a transparent substrate and has a high transmittance characteristic. In the phase-shift blankmask according to the present disclosure, the phase-shift film has a high transmittance of 50% or higher, thereby achieving a micro pattern smaller than or equal to 32 nm, preferably 14 nm, and more preferably 10 nm for a semiconductor device, for example, a DRAM, a flash memory, a logic device.

### CROSS-REFERENCE TO RELATED THE APPLICATION

This application claims priorities from Korean Patent Application Nos. 10-2017-0061699 filed on May 18, 2017 and 10-2018-0048241 filed on Apr. 26, 2018 in the Korean Intellectual Property Office, the disclosure of which is incorporated herein by reference.

### BACKGROUND

### Field

The present disclosure relates to a phase-shift blankmask and a phase-shift photomask, and more particularly to a phase-shift blankmask and a phase-shift photomask, in which a phase-shift film has a high transmittance of 50% or higher with regard to an exposure wavelength in order to improve a margin of depth of focus and exposure latitude at wafer exposure.

### Description of the Related Art

Nowadays, a high-level semiconductor microfabrication technology has become very important to meet demands for high integration of a large-scale integrated circuit and miniaturization of a circuit pattern. In case of a semiconductor integrated circuit, there have been increasing technical demands for miniaturization of circuit wiring for high-speed operation and low power consumption, a contact hall pattern for interlayered connection, and circuit arrangement corresponding to integration.

Like this, in accordance with high integration of a miniaturized pattern, standards for resolution and pattern registration required for a photomask are getting stricter. Further, as a core issue for fabrication of a semiconductor device, it has been on the rise to secure a margin of depth of focus and exposure latitude needed when a complicated multi-layered semiconductor device is fabricated.

The issue is affected by not only a photomask and a process of fabricating a semiconductor device, but also characteristics of a blankmask as a key part in fabricating the semiconductor device. For example, when a semiconductor device is fabricated using a photomask formed by a phase-shift blankmask, a high resolution is achieved with a high image contrast and a margin of depth of focus is improved.

Recently, a phase-shift blankmask has been developed to include a phase-shift film having a higher transmittance of 12%, 18%, 24% or 30% than the existing phase-shift film having a transmittance of 6% as a more precise and micro semiconductor device is required. The phase-shift mask having such a high transmittance has an effect on making the margin of depth of focus and the exposure latitude be more increased than those of the existing phase-shift mask having a transmittance of 6%.

Meanwhile, a phase-shift mask for chromless phase-shift lithography (CPL) for forming a phase-shift pattern by etching a transparent substrate has attracted attention as another phase-shift photomask technology for achieving the phase-shift pattern having a high transmittance. Specifically, the CPL phase-shift mask is formed with a phase-shift pattern having a transmittance of about 100% and a phase-shift amount of 180° by forming a light-shielding film pattern through an etching process after forming a light-shielding film and a resist film pattern on a transparent substrate, and etching the transparent substrate at a predetermined depth by using the light-shielding film pattern as the etching mask, and thus uses the phase-shift pattern as a phase-shifting portion.

However, the CPL phase-shift mask is restrictively utilized since the etching process of the transparent substrate for forming the phase-shift pattern has the following problems.

First, the CPL phase-shift mask is difficult to clearly distinguish an etching end-point since there are no thin film layers for distinguishing the etching end-points against the transparent substrate and there are no differences in a detected amount of a specific material while the substrate is etched. In general, the etching end-point of the thin film is detected based on differences in the detected amount between metal contained in the thin films and light elements including nitrogen (N), oxygen (O), carbon (C). However, it is difficult to detect the etching end-point of the transparent substrate since there are no changes in a specific material. Thus, the phase-shift portion formed by etching the transparent substrate causes problems of a low resolution and the like because the etching of the transparent substrate is performed depending on etching time, and it is therefore difficult to secure phase amount reproducibility and control the etching.

Further, the transparent substrate has high hardness due to a high-temperature heat-treatment process and it is thus difficult to repair defects caused while the transparent substrate is etched. Therefore, the CPL mask is rarely mass-produced and used even though it is excellent in characteristics.

### SUMMARY

Accordingly, an aspect of the present disclosure is to provide a phase-shift blankmask and a phase-shift photomask, to which a phase-shift film having a high transmittance of 50% or higher is applied.

Another aspect of the present disclosure is to provide a phase-shift blankmask and a phase-shift photomask, in which a resist film can be made as a thin film and improved in resolution, critical dimension precision, and linearity.

Still another aspect of the present disclosure is to provide a phase-shift blankmask and a phase-shift photomask, which can achieve a micro pattern of about 32 nm or lower, in particular, about 14 nm or lower with regard to various semiconductor devices.

According to one embodiment of the present disclosure, there is provided a phase-shift blankmask with a phase-shift film provided on a transparent substrate, wherein the phase-shift film is etched by the same material for the transparent substrate, and comprises a material of making an etching end-point be detectable against the transparent substrate.

The phase-shift film may have a transmittance of 50% or higher with regard to exposure light.

The phase-shift film may include silicon (Si) or a silicon (Si) compound.

The material for making the etching end-point be detectable may include nitrogen (N).

A light-shielding film may be further provided on the phase-shift film.

The light-shielding film may include one among chrome (Cr), a chrome (Cr) compound, molybdenum chrome (MoCr) and a molybdenum chrome (MoCr) compound.

A hard mask film may be further provided on a light-shielding film and the phase-shift film which are stacked in sequence.

The hard mask film may include a material having the same etching properties as the phase-shift film, and the same etching selectivity as the light-shielding film.

A resist film may be further provided on the phase-shift film, and a charge dissipation layer may be further provided on the resist film.

The charge dissipation layer may include self-doped water-soluble conducting polymer.

### BRIEF DESCRIPTION OF THE DRAWINGS

The above and/or other aspects will become apparent and more readily appreciated from the following description of exemplary embodiments, taken in conjunction with the accompanying drawings, in which:

FIG. 1 is a cross-section view of a phase-shift blankmask having a high transmittance according to a first structure of the present disclosure;

FIG. 2 is a cross-section view of a phase-shift blankmask having a high transmittance according to a second structure of the present disclosure;

FIGS. 3A and 3B are cross-section views of a phase-shift blankmask having a high transmittance according to a second structure of the present disclosure; and

FIGS. 4A to 4E are cross-section views for explaining a method of fabricating the phase-shift blankmask having the high transmittance according to the second structure of the present disclosure.

### DETAILED DESCRIPTION OF EXEMPLARY EMBODIMENTS

Hereinafter, embodiments of the present invention will be described in more detail with reference to the accompanying drawings. However, the embodiments are provided for illustrative purpose only and should not be construed to limit the scope of the invention. Therefore, it will be appreciated by a person having an ordinary skill in the art that various modifications and equivalents can be made from the embodiments. Further, the scope of the present invention has to be defined in the appended claims.

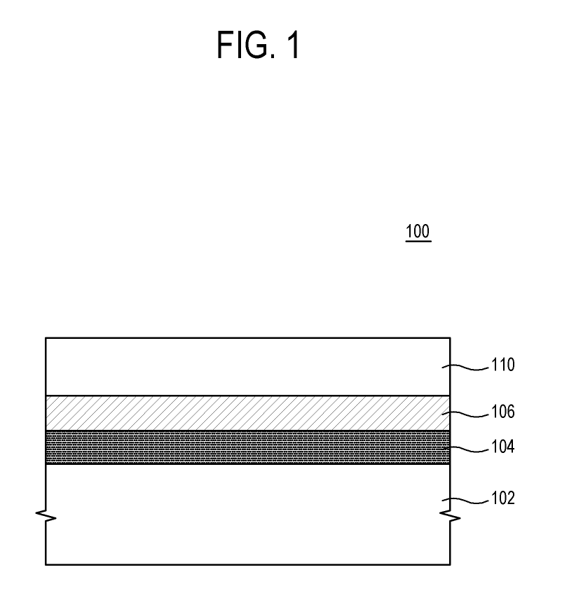

FIG. 1 is a cross-section view of a phase-shift blankmask having a high transmittance according to a first structure of the present disclosure;

Referring to FIG. 1, a phase-shift blankmask 100 according to the present disclosure includes a transparent substrate 102, and a phase-shift film 104, a light-shielding film 106 and a resist film 110 which are sequentially formed on the transparent substrate 102.

The transparent substrate 102 includes quartz glass, synthesized quartz glass or fluorine-doped quartz glass. The flatness of the transparent substrate 102 affects one of the thin films formed thereon, for example, the phase-shift film 104 or the light-shielding film 106, and affects a margin of depth of focus during wafer exposure. Therefore, when the flatness of a surface on which films are grown is defined as a total indicated reading (TIR) value, the value is controlled to be lower than or equal to 1,000 nm, preferably 500 nm, and more preferably, 300 nm within a measuring area of 142 mm² to get a good flatness.

The phase-shift film 104 may include one or more kinds of materials among silicon (Si), molybdenum (Mo), tantalum (Ta), vanadium (V), cobalt (Co), nickel (Ni), zirconium (Zr), niobium (Nb), palladium (Pd), zinc (Zn), chrome (Cr), aluminum (Al), manganese (Mn), cadmium (Cd), magnesium (Mg), lithium (Li), selenium (Se), copper (Cu), hafnium (Hf) and tungsten (W), or one or more kinds of materials among light elements including nitrogen (N), oxygen (O), carbon (C), boron (B) and hydrogen (H) in addition to the material.

In particular, the phase-shift film 104 may include a compound of silicon (Si) to achieve a high transmittance. Specifically, the phase-shift film 104 may include silicon (Si) or a silicon (Si) compound containing one or more kinds of materials selected among SiN, SiC, SiO, SiCN, SiCO, SiNO, SiCON, SiB, SiBN, SiBC, SiBO, SiBCN, SiBCO, SiBNO and SiBCON, which includes one or more light elements among oxygen (O), nitrogen (N), carbon (C) and boron (B) in addition to silicon (Si).

The phase-shift film 104 has a transmittance of 50% or higher, preferably 70% or higher, or more preferably 90% or higher with respect to an exposure wavelength of 193 nm. According to an aspect of the present disclosure, the phase-shift film 104 includes a silicon (Si) compound, and particularly includes a silicon (Si) compound containing oxygen (O) so as to have a high transmittance of 50% or higher. Increase of oxygen (O) contained in the silicon (Si) compound causes a phase-shift film to be decreased in a refractive index (n) and an extinction coefficient (k), thereby ultimately increasing the transmittance and thickness of the phase-shift film.

However, the increased transmittance of the phase-shift film 104 improves destructive interference at the edges of the pattern during the wafer exposure, but the increased thickness increases an aspect ratio of the pattern during the fabrication of the photomask and thus causes pattern collapse. Thus, the content of oxygen (O) contained in the phase-shift film 104 is properly controlled to thereby adjust the transmittance and thickness of the phase-shift film. For example, when a high-transmittance phase-shift mask is fabricated to form a dot pattern of 100 nm, a thickness of 200 nm may be designed by increasing the content of oxygen (O) in order to maintain a pattern aspect ratio of 2 or lower and achieve a high transmittance of 90% or higher. Further, to have the same pattern aspect ratio of 2 or lower while a dot pattern of 70 nm is formed, the thin film has to have a thickness of 140 nm or lower. In this case, for control of a phase amount, the phase-shift film may be fabricated to have a transmittance of 70% by relatively decreasing the content of oxygen (O) or increasing the content of nitrogen (N).

In addition, the content of oxygen (O) and nitrogen (N) contained in the foregoing phase-shift film 104 has to be properly controlled since it is also used for the purpose of checking an etching end-point during the etching. For example, when the content of oxygen (O) is high in the phase-shift film 104, it is difficult to check the etching end-point against the lower transparent substrate 102. Therefore, to check the etching end-point of the phase-shift film 104, the light elements, for example, nitrogen (N), carbon (C), etc. may be included in addition to oxygen (O). Preferably, nitrogen (N) may be included to facilitate the check of the etching end-point. However, when the content of nitrogen (N) contained in the phase-shift film 104 is high, the transmittance of the phase-shift film 104 is decreased with respect to the exposure wavelength. Accordingly, there is a need of properly controlling the content of oxygen (O) and the content of light elements such as nitrogen (N), etc. to make the phase-shift film 106 have a high transmittance and easily determine the etching end-point.

To satisfy the foregoing characteristics, the phase-shift film 104 may have a composition ratio in which silicon (Si) of 10 at %˜40 at % and the light elements (i.e. the sum of N, O, C, etc.) of 60 at %˜90 at % are contained. In particular, it is good when nitrogen (N) among the light elements included in the phase-shift film 104 has a content of 1 at %˜20 at %, and preferably 3 at %˜20 at %. When nitrogen (N) has a content of 1 at % or lower, it is difficult to determine the etching end-point against the lower transparent substrate 102. When nitrogen (N) has a content of 20 at % or higher, it is difficult to guarantee a high transmittance of the phase-shift film 106.

Oxygen (O) among the light elements included in the phase-shift film 104 may have a content of 50 at %˜90 at %. When the content of oxygen (O) is lower than or equal to 50 at %, it is difficult to secure a high transmittance of the phase-shift film 106. When the content of oxygen (O) is equal to or higher than 90 at %, it is difficult to determine the etching end-point against the lower transparent substrate 102.

The phase-shift film 104 is formed by a sputtering process, and the sputtering process may employ a silicon (Si) target or a silicon (Si) target doped with boron (B) to sputtering electrical conductivity. In this case, it is good when the silicon (Si) target doped with boron (B) has a resistivity of 1.0 E−04 Ω·cm˜1.0 E+01 Ω·cm, and preferably 1.0 E−03 Ω·cm˜1.0 E−02 Ω·cm. When the resistivity of the target is high, abnormal electric discharge such as arc occurs during the sputtering process and thus causes defects in the characteristics of the thin film.

Oxygen (O) included in the phase-shift film 104 may be produced using one or more kinds of gases selected from reactive gases such as nitrogen monoxide (NO), nitrogen dioxide (N₂O), carbon dioxide (CO₂), etc. during the sputtering process.

Further, the silicon (Si) target for forming the phase-shift film 104 may be manufactured by a columnar-crystalline or mono-crystalline method.

To minimize defects in the thin film during the sputtering process, content of impurities included in the target may be controlled. To this end, the content of impurities included in the silicon (Si) target, in particular, the content of carbon (C) and oxygen (O) may be lower than or equal to 30 ppm, and preferably 5.0 ppm. Content of impurities other than carbon (C) and oxygen (O), for example, Al, Cr, Cu, Fe, Mg, Na and K may be lower than or equal to 1.0 ppm, and preferably 0.05 ppm. Further, it is good to control the defects when the target is manufactured to have a purity equal to or higher than 4N and preferably 5N by controlling such impurities.

The phase-shift film 104 has one of structures such as a single-layered film having uniform composition, a single-layered continuous film in which composition or a composition ratio is continuously varied, and a multi-layered film in which one or more films different in composition or a composition ratio are stacked as one or more layers.

The phase-shift film 104 may have a thickness of 1,000 Å˜2,000 Å, and preferably 1,100 Å˜1,800 Å, and have a phase amount of 170°˜240°, preferably 180°˜230°, and more preferably 190°˜220° with regard to exposure light having a wavelength of 193 nm. Further, the phase-shift film 104 has a reflectivity of 20% or lower with regard to all wavelengths of 190 nm˜1,000 nm

The phase-shift film 104 may be subjected to heat treatment at a temperature of 100° C.˜1,000° C. in order to release a thin film stress caused when the thin film is formed. The heat-treatment process may employ a vacuum rapid thermal processing device, a furnace, or a hot plate. Further, the heat-treatment process is performed under a gas atmosphere including oxygen (O) or nitrogen (N), so that the surface of the thin film can be improved in characteristics, for example, resistance to chemicals used in cleaning.

When the thin film stress is defined as a TIR, the phase-shift film 104 is fabricated to make the TIR have a change rate of 300 nm or lower and preferably 200 nm between before and after the growth of the film.

The light-shielding film 106 may have various structures such as a single-layered film, a continuous film and a multi-layered film including two or more layers such as a first light-shielding layer and a second light-shielding layer, and may include a material having an etching selectivity equal to or higher than 10 when the phase-shift film 104 is subjected to dry etching.

The light-shielding film 106 may include one or more kinds of materials among molybdenum (Mo), tantalum(Ta), nickel (Ni), zirconium (Zr), niobium (Nb), palladium (Pd), zinc (Zn), tin (Sn), chrome (Cr), aluminum (Al), manganese (Mn), cadmium (Cd), magnesium (Mg), lithium (Li), selenium (Se), hafnium (Hf) and tungsten (W), or one or more kinds of light elements among nitrogen (N), oxygen (O) and carbon (C) in addition to the material. In particular, the light-shielding film 106 may include a metal compound containing chrome (Cr). When the light-shielding film 106 includes the chrome (Cr) compound, a composition ratio is achieved with chrome (Cr) of 30 at %˜70 at %, nitrogen (N) of 10 at % 40 at %, oxygen (O) of 0˜50 at %, and carbon (C) of 0˜30 at %.

The light-shielding film 106 may include a compound containing chrome (Cr) and molybdenum (Mo), in which the content of molybdenum (Mo) increases the etching rate and the extinction coefficient, and it is thus possible to make the light-shielding film 106 as the thin film. In this case, the compound may be achieved by one of molybdenum-chromate (MoCr) compounds having a composition ratio with molybdenum (Mo) of 2 at %˜30 at %, chrome (Cr) of 30 at %˜60 at %, nitrogen (N) of 10 at %˜40 at %, oxygen (O) of 0˜50 at %, and carbon (C) of 0˜30 at %.

The light-shielding film 106 has a thickness of 500 Å ˜1,000 Å, and preferably 500 Å˜800 Å.

Further, although it is not illustrated, an antireflection film for preventing reflection of exposure light may be additionally provided on the light-shielding film 106, and the antireflection film may be made of a material having the same etching properties or the same etching selectivity as the light-shielding film 106.

The thin film on which the phase-shift film 104 and the light-shielding film 106 are stacked has an optical density of 2.5˜3.5 and preferably 2.7˜3.2, and a surface reflectivity of 10%˜40% and preferably 20%˜35% with regard to the exposure light having a wavelength of 193 nm.

The light-shielding film 106 may be selectively subjected to the heat treatment. In this case, a heat treatment temperature may be lower than or equal to the heat treatment temperature for the lower phase-shift film 104.

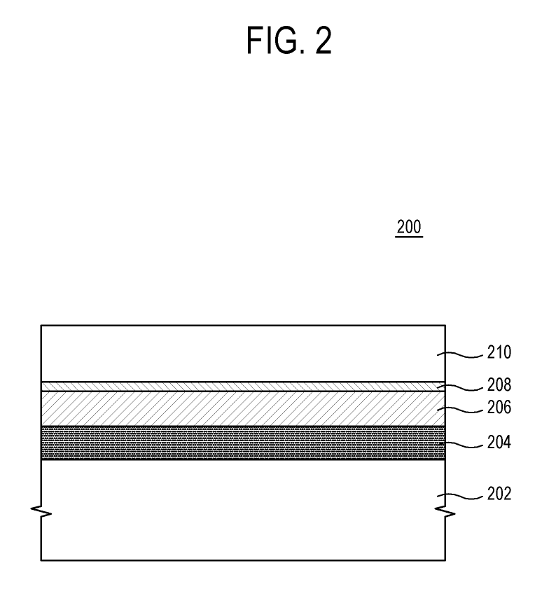

FIG. 2 is a cross-section view of a phase-shift blankmask having a high transmittance according to a second structure of the present disclosure.

Referring to FIG. 2, a phase-shift blankmask 200 having a high transmittance according to the present disclosure includes a transparent substrate 202, and a phase-shift film 204, a light-shielding film 206, a hard mask film 208 and a resist film 210 which are sequentially formed on the transparent substrate 202. Here, the transparent substrate 202, the phase-shift film 204 and the light-shielding film 206 are equivalent to those described above according the first structure of the present disclosure.

The hard mask film 208 is formed on the light-shielding film 206 and serves as an etching mask when the light-shielding film 206 is patterned. Thus, the hard mask film 208 may have an etching selectivity equal to or higher than 10 with respect to the lower light-shielding film 206.

The hard mask film 208 may include a material having the same etching properties as the phase-shift film 204 to simplify the process of fabricating the photomask, and the patterned hard mask film 208 are removed during the etching process for patterning the phase-shift film 204.

Thus, the hard mask film 208 may for example include one of silicon (Si); a silicon (Si) compound such as SiN, SiC, SiO, SiCN, SiCO, SiNO, SiCON, SiB, SiBN, SiBC, SiBO, SiBCN, SiBCO, SiBNO and SiBCON, which includes one or more light elements among oxygen (O), nitrogen (N) and carbon (C) in addition to silicon (Si); molybdenum silicide (MoSi); and a molybdenum silicide (MoSi) compound such as MoSiN, MoSiC, MoSiO, MoSiCN, MoSiCO, MoSiNO and MoSiCON.

The hard mask film 208 has a thickness of 20 Å˜200 Å, and preferably 50 Å˜150 Å. The hard mask film 208 has an etching rate lower than or equal to 10 Å/sec.

The resist film 210 formed on the hard mask film 208 may use a positive or negative chemically amplified resist. The resist film 210 has a thickness of 400 Å˜1,500 Å and preferably 600 Å˜1,200 Å.

Although it is not illustrated, hexamethyldisilazane (HMDS) may be selectively applied for improving adhesion between the resist film 210 and the lower thin film.

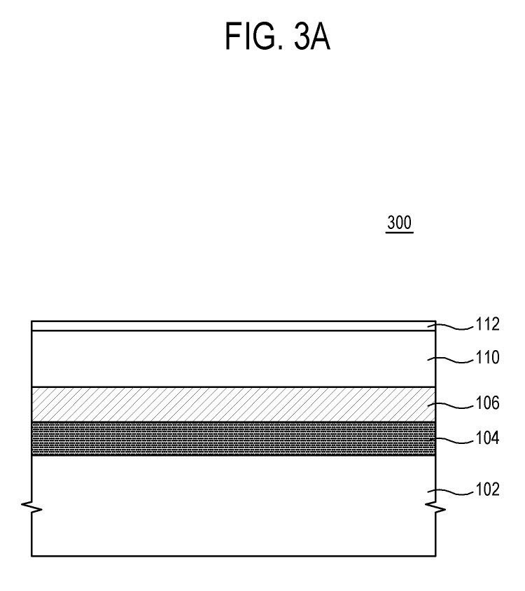

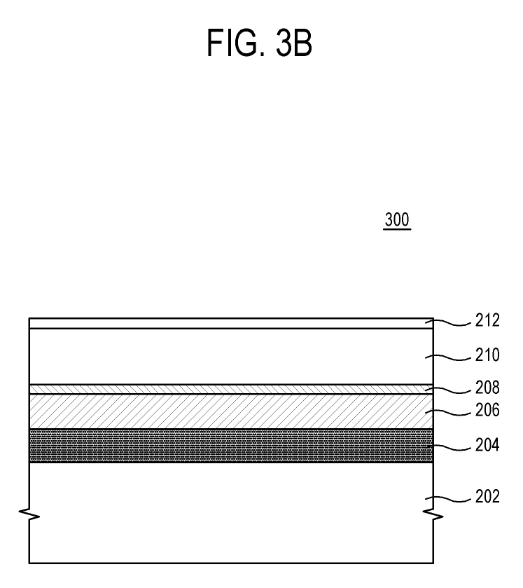

FIGS. 3A and 3B are cross-section views of a phase-shift blankmask having a high transmittance according to a second structure of the present disclosure.

Referring to FIG. 3A and FIG. 3B, a phase-shift blankmask 300 having a high transmittance according to the present disclosure includes charge dissipation layers (CDLs) 112 and 212 respectively formed on the resist films 110 and 210 according to the first structure and the second structure. Here, the transparent substrates 102 and 202, the phase-shift films 104 and 204, the light-shielding films 106 and 206, and the hard mask film 208 are equivalent to those described above according to the first and second structures of the present disclosure.

The charge dissipation layers 112 and 212 may be selectively formed on the resist film, and may include self-doped water-soluble conducting polymer having characteristics to be soluble in deionized (DI) water. With this structure, it is possible to prevent a charge-up phenomenon of an electron during the exposure, and prevent the resist films 110 and 210 from being thermally deformed due to the charge-up phenomenon.

The charge dissipation layers 112 and 212 may have a thickness of 5 nm˜60 nm and preferably 5 nm˜30 nm.

As described above, the present disclosure employs a phase-shift photomask including a phase-shift film having a high transmittance of 50% or higher with regard to an exposure wavelength, and thus enhances a process yield by not only making a resolution higher but also increasing a margin of depth of focus and exposure latitude during wafer exposure for fabricating a semiconductor device.

Further, the present disclosure employs a hard mask film in forming a pattern, thereby making a resist film as a thin film and thus improving resolution, critical dimension precision, and linearity.

Further, the present disclosure employs a phase-shift blankmask having a high transmittance to increase a process window and thus enhance a process yield when various semiconductor devices, for example, a dynamic random access memory (DRAM), a flash memory, a logic device, etc. are fabricated.

Below, a phase-shift blankmask will be described in detail according to embodiments of the present disclosure.

### EMBODIMENTS

### Embodiment 1: A Fabrication Method for a Blankmask and a Photomask (with a Transmittance of about 70% PSM)

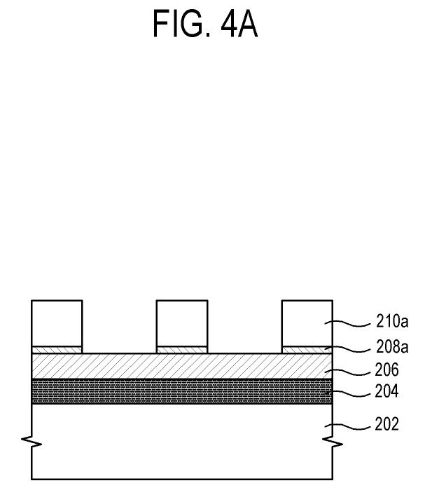

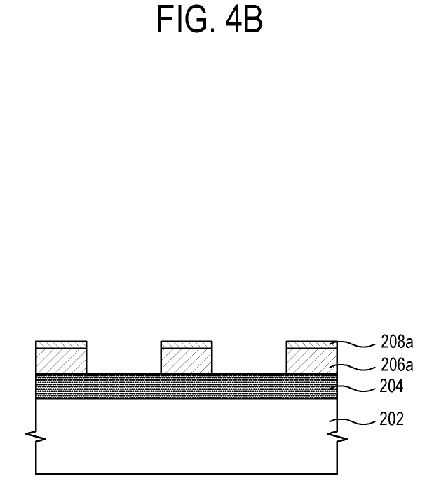

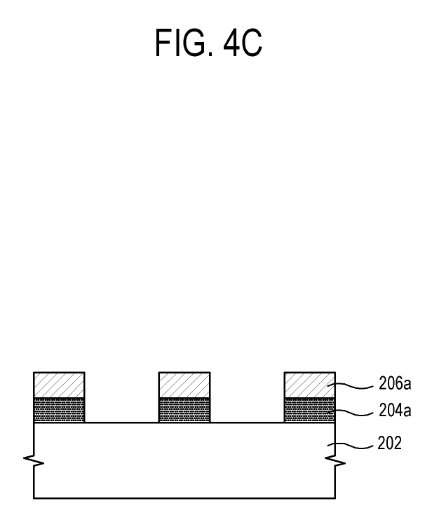

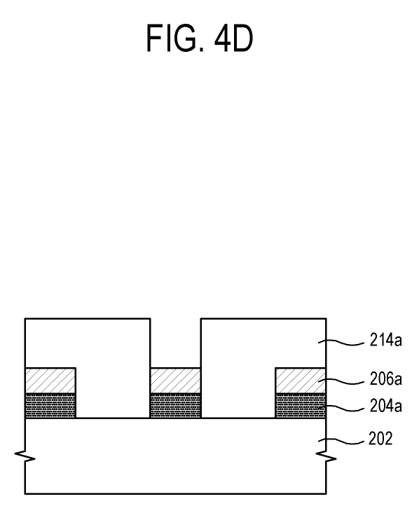

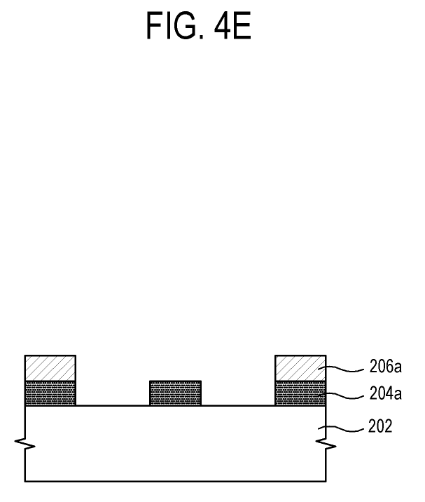

This embodiment will be described with reference to FIGS. 4A to 4E so as to describe the fabrication method for the phase-shift blankmask having a high transmittance and the photomask according to the second structure of the present disclosure.

Referring to FIG. 4A, the phase-shift film 204, the light-shielding film 206, the hard mask film 208 and the resist film 210 are formed in sequence on the transparent substrate 202.

The transparent substrate 202 has a concave shape, and has a TIR value of −82 nm when its flatness is defined as the TIR.

The phase-shift film 204 was fabricated as a film of SiON using a columnar-crystalline method to have a purity of 6N and a thickness of 125 nm by injecting a process gas of Ar:N₂:NO=5 sccm:5 sccm:5.3 sccm into and supplying process power of 1.0 kW to a single-wafer type direct current (DC) magnetron sputtering device mounted with the boron (B)-doped silicon (Si) target.

As results of measuring the transmittance and phase amount of the phase-shift film 204 through the n&k Analyzer 3700RT, a transmittance central value was 68%, a phase amount central value was 205° with respect to the wavelength of 193 nm. Further, a flatness was measured as a convex value of +80 nm. Further, as a result of analyzing a composition ratio of the phase-shift film 204 through the AES, the composition ratio of silicon (Si):nitrogen (N):oxygen (O) was 16.3 at %:15.6 at %:68.1 at %.

Then, to improve the flatness, the phase-shift film 204 was subjected to heat treatment at a temperature of 500° C. for 40 minutes through the vacuum rapid thermal process device. As a result of measuring the stress of the phase-shift film 204, a convex value of +30 nm was obtained, and a stress change (i.e. delta stress) of the whole phase-shift film 204 was +112 nm. This means that the stress is released by the heat treatment.

The light-shielding film 206 was fabricated as a lower-layered film of CrCN to have a thickness of 43 nm by injecting a process gas of Ar:N₂:CH₄=5 sccm:12 sccm:0.8 sccm into and supplying process power of 1.4 kW to a single-wafer type DC magnetron sputtering device mounted with the chrome (Cr) target. Then, an upper-layered film of CrON was fabricated to have a thickness of 16 nm by injecting a process gas of Ar:N₂:NO=3 sccm:10 sccm:5.7 sccm and supplying process power of 0.62 kW, thereby making a double-layered structure.

Then, as results of measuring the optical density and the reflectivity with regard to the light-shielding film 206, the light-shielding film 206 showed an optical density of 3.10 and a reflectivity of 29.6% with respect to the exposure light having the wavelength of 193 nm. This means that there are no problems of using the fabricated light-shielding film as the light-shielding film 206.

The hard mask film 208 was fabricated as a film of SiON to have a thickness of 10 nm by injecting a process gas of Ar:N₂:NO=7 sccm:7 sccm:5 sccm into and supplying process power of 0.7 kW to a single-wafer type DC magnetron sputtering device mounted with the silicon (Si) target.

Next, the HMDS was applied to the hard mask film 208, and then the negative chemically amplified resist was formed to have a thickness of 100 nm by a spin coating system, and thus the phase-shift blankmask was completely fabricated.

After applying the exposure process to the blankmask fabricated as described above, post exposure bake (PEB) was performed at a temperature of 100° C. for 10 minutes, and developed to form a resist film pattern 210a.

Then, the resist film pattern 210a was used as an etching mask so that the hard mask film below was subjected to fluorine-based dry etching, thereby forming a hard mask film pattern 208a. In this case, as a result of measuring the hard mask film by an etching end point detection (EPD) system, it was 17 seconds.

Referring to FIG. 4B, the resist film pattern was removed, and then the lower light-shielding film was etched using the hard mask film pattern 208a as the etching mask, thereby forming a light-shielding film pattern 206a. Alternatively, the light-shielding film may be etched using the resist film and the hard mask film as the etching mask.

Referring to FIG. 4C, the hard mask film pattern 208a and the light-shielding film pattern 206a were used as the etching mask to apply fluorine-based dry etching to the lower phase-shift film, thereby forming a phase-shift film pattern 204a.

In this case, as a result of analyzing the etching end-point of the phase-shift film pattern 204a by the EPD system, it was possible to distinguish the etching end-point against the lower transparent substrate 202 by using a nitrogen (N) peak. Here, the hard mask film pattern 208a was fully removed when the etching is performed to form the phase-shift film pattern 204a.

Referring to FIG. 4D and FIG. 4E, a second resist film pattern 214a was formed on the transparent substrate 202 formed with the phase-shift film pattern 204a, and then the light-shielding film pattern 206a of an exposed main area except an outer circumferential area was removed to thereby completely fabricate the phase-shift photomask.

With regard to the phase-shift photomask fabricated as described above, the pure transmittance and phase amount of the phase-shift film pattern were measured using the MPM-193. In result, the transmittance was 72.3% and the phase amount was 215° at the wavelength of 193 nm. Further, a pattern profile was 86° as a measured result of using the TEM.

### Embodiment 2: A Fabrication Method for a Blankmask and a Photomask (with a Transmittance of about 100% PSM)

In this embodiment, the phase-shift photomask was fabricated to have a higher transmittance of the phase-shift film pattern as compared with that of the embodiment 1.

First, the same sputtering target and device as those of the embodiment 1 were prepared to inject the process gas of Ar:N₂:NO=5 sccm:5 sccm:7.1 sccm and supply the process power of 1.0 kW, thereby forming a film of SiON having a thickness of 160 nm.

As results of measuring the transmittance and phase amount of the formed phase-shift film 104 through the n&k Analyzer 3700RT, the transmittance was 87% and the phase amount was 204′ with respect to the wavelength of 193 nm. Further, as a result of analyzing a composition ratio of the phase-shift film fabricated as above through the AES, the composition ratio of silicon (Si):nitrogen (N):oxygen (O) was 21.2 at %:4.0 at %:74.8 at %.

Further, the phase-shift film pattern was fabricated by the photomask process after the light-shielding film, the hard mask film and the resist film are stacked in sequence like those of the embodiment 1, and the pure transmittance and phase amount of the phase-shift film pattern were measured using the MPM-193. In result, the transmittance was 97.2%, and the phase amount was 213°.

### Comparative Example: Fabrication of Substrate-Etching Type Phase-Shift Blankmask

In this comparative example, a substrate-etching type phase-shift blankmask and photomask were fabricated for comparison with the embodiment 1.

First, the substrate-etching type blankmask was fabricated on the transparent substrate as a lower-layered film of CrCN to have a thickness of 43 nm by injecting a process gas of Ar:N₂:CH₄=5 sccm:5 sccm:0.8 sccm into and supplying process power of 1.4 kW to a single-wafer type DC magnetron sputtering device mounted with the chrome (Cr) target. Then, an upper-layered film was fabricated as a film of CrON to have a thickness of 16 nm by injecting a process gas of Ar:N₂:NO=3 sccm:10 sccm:5.7 sccm and supplying process power of 0.62 kW, thereby forming a double-layered structure.

Here, as results of measuring the optical density and the reflectivity of the light-shielding film, the light-shielding film showed an optical density of 3.05 and a reflectivity of 31.2% with regard to the exposure light having a wavelength of 193 nm.

Then, the negative chemically amplified resist was formed to have a thickness of 170 nm on the hard mask film by the spin coating system, and thus the phase-shift blankmask was completely fabricated.

Next, the resist film pattern was formed, and then the lower light-shielding film was etched using the resist film pattern as the etching mask, thereby forming the light-shielding film pattern. Then, the resist film was removed, and the lower exposed transparent substrate was etched based on the fluorine (F) gas using the light-shielding film pattern as the etching mask.

In this case, an etching time was set to etch the transparent substrate, and the etched transparent substrate showed a thickness of 200 nm and a phase amount of 220°.

Regarding the phase-shift portion of the phase-shift photomask according to the embodiment 1 and the phase-shift portion of the substrate-etching type phase-shift photomask fabricated as described according to the comparative example, results of measuring uniformity are tabulated as follows.

TABLE 1

| | | | | | | | Range |
|---|---|---|---|---|---|---|---|
| | | Point | Point | Point | Point | Point | (Max- |
| | | #1 | #2 | #3 | #4 | #5 | Min) |
| transmittance | embodiment 1 | 72.3% | 72.9% | 73.2% | 72.2% | 71.8% | 1.4% |
| @193 nm | comparative | 99.8% | 100% | 99.2% | 100% | 99.3% | 0.8% |
| | example | | | | | | |
| phase amount | embodiment 1 | 215.2° | 215.3° | 216.2° | 215.0° | 215.2° | 1.2° |
| @193 nm | comparative | 219° | 220° | 225° | 217° | 22° | 8° |
| | example | | | | | | |

Referring to Table 1, there was an insignificant difference in range of transmittance between the embodiment and the comparative example. On the other hand, the phase amount according to the embodiment 1 showed a range of 1.2°, but the phase amount according to the comparative example showed a range of 8°. Therefore, it will be understood that the substrate-etching type phase-shift photomask is hardly usable.

Regarding the foregoing transmittance and phase amount, five sheets of phase-shift photomask according to the embodiment 1 and five sheets of phase-shift photomask the comparative example were fabricated, and a reproducibility test process of measuring their central values was performed, of which the results are shown in the following Table 2.

TABLE 2

| | | | | | | | Lot-to- |
|---|---|---|---|---|---|---|---|
| | | | | | | | lot |
| | | Point | Point | Point | Point | Point | (Max- |
| | | #1 | #2 | #3 | #4 | #5 | Min) |
| transmittance | embodiment 1 | 72.5% | 72.2% | 72.7% | 73.2% | 73.6% | 0.014% |
| @193 nm | comparative | 99% | 98% | 99% | 99% | 99% | 0.01% |
| | example | | | | | | |
| phase amount | embodiment 1 | 215° | 214° | 215° | 216° | 215° | 2° |
| @193 nm | comparative | 220° | 216° | 224° | 226° | 213° | 13° |
| | example | | | | | | |

Referring to Table 2, there is a slight difference between the embodiment 1 and the comparative example since their transmittance central values corresponding to the plates are similar to each other. On the other hand, the embodiment 1 showed a phase amount of 2°, but the comparative example showed a phase amount of 13°. Therefore, it will be understood that the comparative example is relatively difficult to control the phase amount.

The present disclosure employs a phase-shift photomask including a phase-shift film having a high transmittance of 50% or higher with regard to an exposure wavelength, and thus enhances a process yield by not only making a resolution higher but also increasing a margin of depth of focus and exposure latitude during wafer exposure for fabricating a semiconductor device.

Further, the present disclosure employs a hard mask film in forming a pattern, thereby making a resist film as a thin film and thus improving resolution, critical dimension precision, and linearity.

Further, the present disclosure employs a phase-shift blankmask having a high transmittance to increase a process window and thus enhance a process yield when various semiconductor devices, for example, a DRAM, a flash memory, a logic device, etc. are fabricated.

Although the present disclosure have been shown and described with exemplary embodiments, the technical scope of the present disclosure is not limited to the scope disclosed in the foregoing embodiments. Therefore, it will be appreciated by a person having an ordinary skill in the art that various changes and modifications may be made from these exemplary embodiments. Further, it will be apparent as defined in the appended claims that such changes and modifications are involved in the technical scope of the present disclosure.

What is claimed is:

1. A phase-shift blankmask comprising a phase-shift film provided on a transparent substrate,
wherein the phase-shift film is etched by a same material for the transparent substrate, and comprises a material of making an etching end-point be detectable against the transparent substrate.

2. The phase-shift blankmask according to claim 1, wherein the phase-shift film has a transmittance of 50% or higher with regard to exposure light.

3. The phase-shift blankmask according to claim 1, wherein the phase-shift film comprises silicon (Si), or one of silicon (Si) compounds such as SiN, SiC, SiO, SiCN, SiCO, SiNO, SiCON, SiB, SiBN, SiBC, SiBO, SiBCN, SiBCO, SiBNO and SiBCON, which contains one or more light elements in addition to silicon (Si).

4. The phase-shift blankmask according to claim 3, wherein, when the phase-shift film comprises the silicon (Si) compound, a composition ratio is achieved with silicon (Si) of 10 at %˜40 at % and the light elements of 60 at %˜90 at %.

5. The phase-shift blankmask according to claim 1, wherein the material for making the etching end-point be detectable comprises nitrogen (N).

6. The phase-shift blankmask according to claim 5, wherein, when the phase-shift film comprises nitrogen (N), nitrogen (N) has a content of 1 at %˜20 at %.

7. The phase-shift blankmask according to claim 1, wherein, when the phase-shift film comprises oxygen (O), oxygen (O) has a content of 50 at %˜90 at %.

8. The phase-shift blankmask according to claim 3, wherein the phase-shift film is formed using a silicon (Si) target or a boron (B)-doped silicon (Si) target, and the target has a resistivity of 1.0 E−04 Ω·cm˜1.0 E+01 Ω·cm.

9. The phase-shift blankmask according to claim 1, wherein the phase-shift film has one of structures such as a single-layered film in which composition is uniform, a single-layered continuous film in which composition or a composition ratio is continuously varied, and a multi-layered film in which one or more films different in composition or a composition ratio are stacked as one or more layers.

10. The phase-shift blankmask according to claim 1, wherein the phase-shift film has a thickness of 1,000 Å˜2,000 Å.

11. The phase-shift blankmask according to claim 1, wherein the phase-shift film has a phase amount of 170°˜240° with regard to exposure light having a wavelength of 193 nm.

12. The phase-shift blankmask according to claim 1, further comprising a light-shielding film provided on the phase-shift film.

13. The phase-shift blankmask according to claim 12, wherein the light-shielding film comprises one of chrome (Cr); a chrome (Cr) compound having a composition ratio with chrome (Cr) of 30 at %˜70 at %, nitrogen (N) of 10 at % 40 at %, oxygen (O) of 0˜50 at %, carbon (C) of 0˜30 at %; molybdenum chrome (MoCr); and a molybdenum chrome (MoCr) compound having a composition ratio with molybdenum (Mo) of 2 at %˜30 at %, chrome (Cr) of 30 at %˜60 at %, nitrogen (N) of 10 at %˜40 at %, oxygen (O) of 0˜50 at %, and carbon (C) of 0˜30 at %.

14. The phase-shift blankmask according to claim 12, wherein the light-shielding film has a thickness of 500 Å˜1,000 Å.

15. The phase-shift blankmask according to claim 1, further comprising an antireflection film provided on the light-shielding film,
wherein the antireflection film comprises a material having same etching properties or same etching selectivity as the light-shielding film.

16. The phase-shift blankmask according to claim 12, wherein the light-shielding film or the structure where the light-shielding film is stacked on the phase-shift film has an optical density of 2.5˜3.5 with regard to exposure light.

17. The phase-shift blankmask according to claim 12, wherein a stacking portion between the phase-shift film and the light-shielding film has a surface reflectivity of 10%˜40%.

18. The phase-shift blankmask according to claim 12, further comprising a hard mask film provided on the light-shielding film and the phase-shift film which are stacked in sequence.

19. The phase-shift blankmask according to claim 18, wherein the hard mask film comprises a material having same etching properties as the phase-shift film, and same etching selectivity as the light-shielding film.

20. The phase-shift blankmask according to claim 18, wherein the hard mask film comprises one of silicon (Si); a silicon (Si) compound such as SiN, SiC, SiO, SiCN, SiCO, SiNO, SiCON, SiB, SiBN, SiBC, SiBO, SiBCN, SiBCO, SiBNO and SiBCON, which contains one or more light elements in addition to silicon (Si); molybdenum silicide (MoSi); and a molybdenum silicide (MoSi) compound such as MoSiN, MoSiC, MoSiO, MoSiCN, MoSiCO, MoSiNO and MoSiCON.

21. The phase-shift blankmask according to claim 18, wherein the hard mask film has an etching rate of 10 Å/sec or lower.

22. The phase-shift blankmask according to claim 18, wherein the hard mask film has a thickness of 20 Å˜200 Å.

23. The phase-shift blankmask according to claim 1, wherein further comprising a resist film provided on the phase-shift film, and a charge dissipation layer provided on the resist film.

24. The phase-shift blankmask according to claim 23, wherein the charge dissipation layer comprises self-doped water-soluble conducting polymer.

25. The phase-shift blankmask according to claim 23, wherein the charge dissipation layer has a thickness of 5 nm˜60 nm.

26. The phase-shift blankmask according to claim 1, wherein a phase-shift photomask fabricates using the phase-shift blankmask.
